(19) United States
(12) Patent Application Publication
(10) Pub. No.: US 2011/0282603 A1
(43) Pub. Date: Nov. 17, 2011

(54) TECHNIQUES FOR DETERMINING PLATFORM ENERGY USAGE

(76) Inventors: MILAN MILENKOVIC, Portland, OR (US); Prashant Gandhi, Gilroy, CA (US); Ulf R. Hanebutte, Gig Harbor, WA (US)

(21) Appl. No.: 13/174,126

(22) Filed: Jun. 30, 2011

(51) Int. Cl. G01R 21/00; G06F 19/00

(52) U.S. Cl. 702/62; 702/61

(57) ABSTRACT

Techniques for monitoring platform energy consumption. One or more operational states of the platform are monitored during a period of time. For each of the one or more operational states, a portion of the period of time that the platform was in the respective one or more operational states is determined. Energy consumption information corresponding to the one or more operational states is retrieved. The energy consumption information and the portions of the period of time are utilized to determine an energy consumption for the period of time.

### TECHNICAL FIELD

Embodiments of the invention relate to techniques for determining energy usage. More particularly, embodiments of the invention relate to techniques for utilization of software to monitor and evaluate platform energy usage.

### BACKGROUND

Tracking energy usage is increasingly important in many settings. For example, many regulations require that commercial buildings conform to certain energy efficiency requirements. In order to monitor compliance, energy usage must me measured in some way. Typical measurement techniques are based on dedicated hardware monitors, which can be expensive and complex.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram of one embodiment of an architecture for monitoring energy consumption.

FIG. 2 is a block diagram of one embodiment of an energy agent for monitoring platform energy usage.

FIG. 3 is a flow diagram of one embodiment of a technique for monitoring energy usage of a platform.

FIG. 4 is a block diagram of one embodiment of an electronic system.

### DETAILED DESCRIPTION

In the following description, numerous specific details are set forth. However, embodiments of the invention may be practiced without these specific details. In other instances, well-known circuits, structures and techniques have not been shown in detail in order not to obscure the understanding of this description.

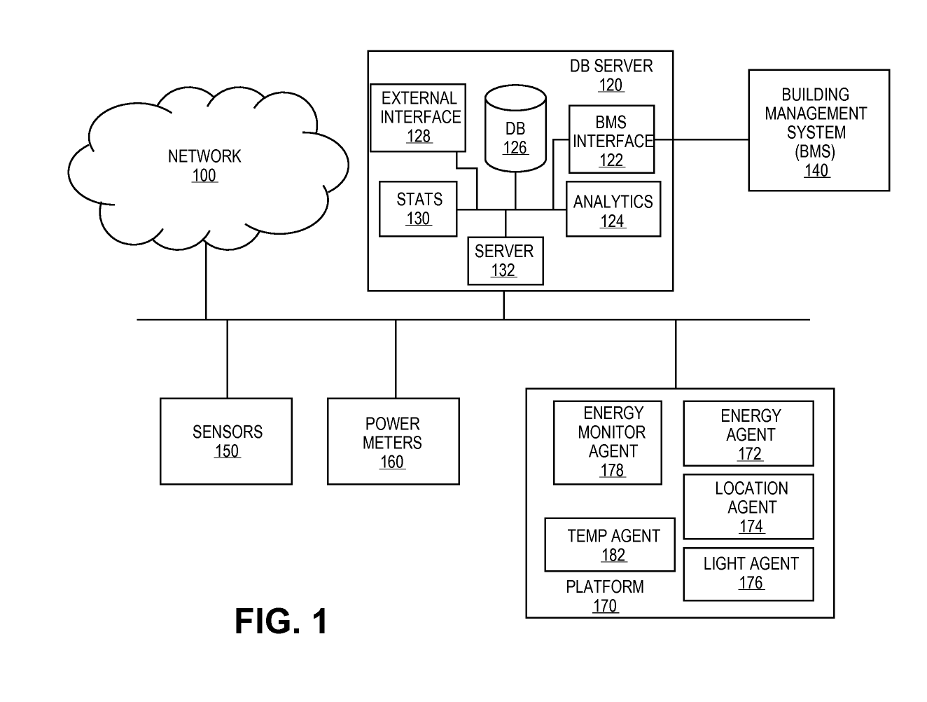

FIG. 1 is a block diagram of one embodiment of an architecture for monitoring energy consumption. The architecture of FIG. 1 allows for a two-way communication between an individual user of a platform and a building infrastructure including a building management system. This may provide for better feedback to a user as well as a better aggregate view of energy consumption.

Network 100 provides an interconnection between multiple electronic devices. Network 100 may provide communication with any number of remote devices not illustrated in FIG. 1. Network 100 may be, for example, the Internet.

Database (DB) server 120 may be coupled with network 100 and other systems. DB server 120 may also be coupled with building management system (BMS) 140 that may include information from, or access to (e.g., request certain actions or information), building systems (e.g., HVAC, electrical, hydraulic, automation) that may provide energy consumption data. DB server 120 may be coupled with BMS 140 via BMS interface 122, which may be one or more wired and/or wireless interfaces.

DB server 120 includes database (DB) 126, which is used to store information retrieved by, sent to, or otherwise acquired by DB server 120. In one embodiment, DB 126 stores energy consumption information gathered from the components illustrated in FIG. 1 as well as any other components. External interface(s) 128 provides one or more wired and/or wireless interfaces between DB server 120 and other sensors or components (not illustrated in FIG. 1).

Statistics 130 may be statistics that are derived by DB server 120 or are provided to DB server 120. Statistics 130 may be used to provide energy consumption information and/or to analyze and derive energy consumption information. Analytics 124 represent logic (e.g., hardware, software, firmware, any combination thereof) that provides analysis of the information stored by DB server 120. For example, analytics 124 may provide macro or micro analysis of energy consumption information as described herein. Server 132 provides services from DB server 120 to devices coupled with DB server 120.

Sensors 150 may be any sensors that provide information to any of the devices of FIG. 1. Sensors 150 may be any type of sensors, for example, temperature sensors, light sensors, wind sensors, etc. Sensors 150 may also include soft sensors, for example, a software agent that provides data in sensor format derived from other forms of data, such as a weather station report. Power meters 160 may be any power meters that provide power information to any of the devices of FIG. 1. Power meters 160 may be any type of power meters that monitor power, for example, at power outlets, light fixtures, or power consumption of any other electrical device.

Platform 170 represents any number of similar platforms that may be coupled with one or more networks interconnected with DB server 120 and/or other devices of FIG. 1. Platform 170 may be, for example, a laptop computer, a desktop computer, or any other device that may be utilized to provide some or all of the information described herein.

In one embodiment, platform 170 includes one or more of the agents illustrated in FIG. 1 in addition to logical and computational components not illustrated in FIG. 1. Energy monitoring agent may 178 provide energy monitoring feedback and functionality to a user of platform 170. Temperature agent 182 may monitor temperature conditions in and/or around platform 170. For example, temperature agent 182 may monitor the ambient temperature of the space in which platform 170 resides, or may monitor the temperature of platform 170.

Energy agent 172 monitors and/or computes, or otherwise determines energy consumption of platform 170. Energy agent 172 may operate as described herein to determine energy consumption. Location agent 174 operates to determine the position of platform 170. Location agent 174 may use global positioning system (GPS) technology, or other techniques for determining the location of platform 170.

Light agent 176 monitors light levels around platform 170. Light agent 176 may include, for example, an ambient light sensor. Light agent 176 may also calculate or otherwise determine light conditions in and around platform 170.

Conceptually, the techniques described herein operate by tracking the time that the monitored system (e.g., platform 170) spends in various operational states—such as running, idle, off—and by multiplying the time spent in each state with platform power drawn in each state to compute energy usage (energy=power×time). In one embodiment, there is provided (1) the ability to detect operational states of the monitored system and times spent in those operational states, and (2) information related to power consumption in each of the relevant operational states of the monitored system.

This principle may be applied to any electronic equipment or device (e.g., HVAC system) that has operational states with specific energy consumption, such as desktop computers or laptops, by providing a software agent to track platform power state occupancy using, for example, system calls, then compute energy usage by integrating over time state occupancy with power consumed in each state, thus yielding energy consumption in KWh. Non-electrical energy consumption can also be monitored, for example, a state of a heating system may be monitored and energy consumption may be determined by using the state of the heating system along with the amount of natural gas consumed in each state to determine an energy usage. This technique is applicable to other situations as well.

State-specific power usage of individual platforms required by this calculation may be measured by commercial instruments (one time bench/lab measurement per supported platform) or provided as specifications by vendors through machine-readable methods, such as an online web service. Note that vendors already measure and report these kinds of values to standards and rating bodies, such as ECMA and EnergyStar.

The energy-tracking agent(s) may reside on the platform or elsewhere in the infrastructure (e,g, a cloud service or with one device acting as proxy for another-PC for a printer). Currently energy measurement is performed via expensive external hardware power meters.

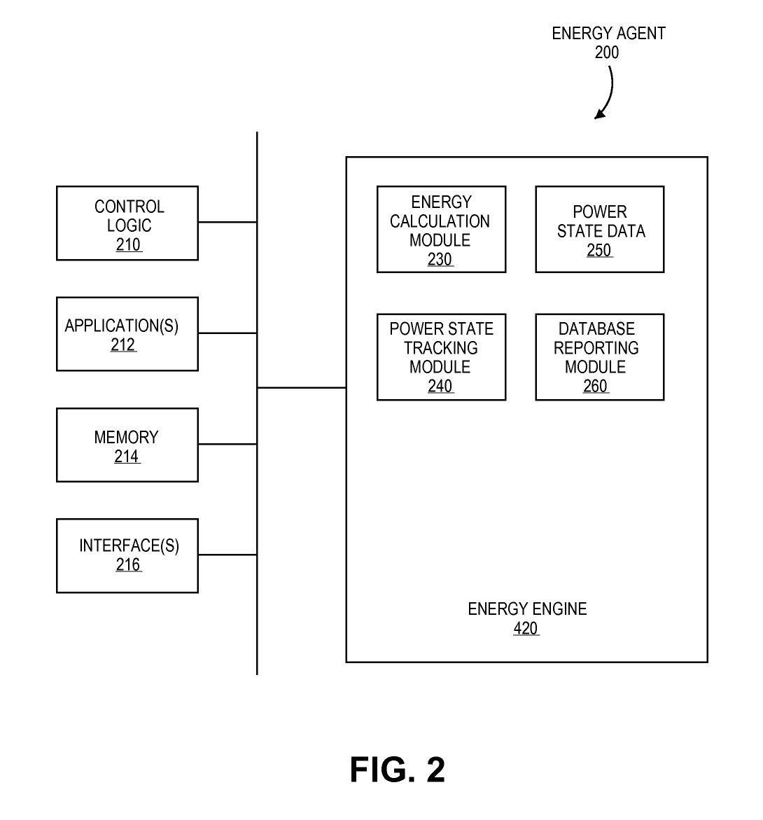

FIG. 2 is a block diagram of one embodiment of an energy agent for monitoring platform energy usage. Energy agent 200 includes control logic 210, which implements logical functional control to direct operation of energy agent 200, and/or hardware associated with directing operation of energy agent 200. Logic may be hardware logic circuits and/or software routines. In one embodiment, energy agent 200 includes one or more applications 212, which represent code sequence and/or programs that provide instructions to control logic 210.

Energy agent 200 includes memory 214, which represents a memory device and/or access to a memory resource for storing data and/or instructions. Memory 214 may include memory local to energy agent 200, as well as, or alternatively, including memory of the host system on which energy agent 200 resides. Energy agent 200 also includes one or more interfaces 216, which represent access interfaces to/from (e.g., an input/output interface, application programming interface) energy agent 200 with regard to entities (electronic or human) external to energy agent 200.

Energy agent 200 also includes energy engine 220, which represents one or more functions that enable energy agent 200. Example modules that may be included in energy engine 220 include energy calculation module 230, power state tracking module 240, power state data module 250 and database reporting module 260. As used herein, a module refers to routine, a subsystem, etc., whether implemented in hardware, software, firmware or some combination thereof.

Energy calculation module 230 computes energy usage based on power state occupancy and time. Power state tracking module 240 tracks and records power state occupancy of the monitored platform. Power state data 250 obtains power-state values for the specific platform (e.g. implemented as cloud web service, stored locally). Database reporting module 260 reports measured (computed) values to external aggregators or repositories (e.g. sensor database).

In addition to the observed performance states, the smart battery information available via, for example, ACPI (a standard for PC systems) may be utilized to obtain the battery capacity changes during a sampling interval, both while the system is running on battery (i.e. battery discharge) and when the system is charging the battery.

The battery charge/discharge information may be used by the power model in addition to the state information and the power consumption of each state to derive a total power consumption of the system over the previous time interval.

In one embodiment, energy consumption calculation is performed only when the system is plugged into an active power outlet. Battery charging/discharging model is of interest because the monitored system (e.g. a laptop) tends to draw higher power when connected to a power outlet with only partially charged battery (i.e. after it was running in battery-only mode). Additional detailed power consumption information of platform components, if available (e.g. by exposed internal platform counters) can be added to the above described power model.

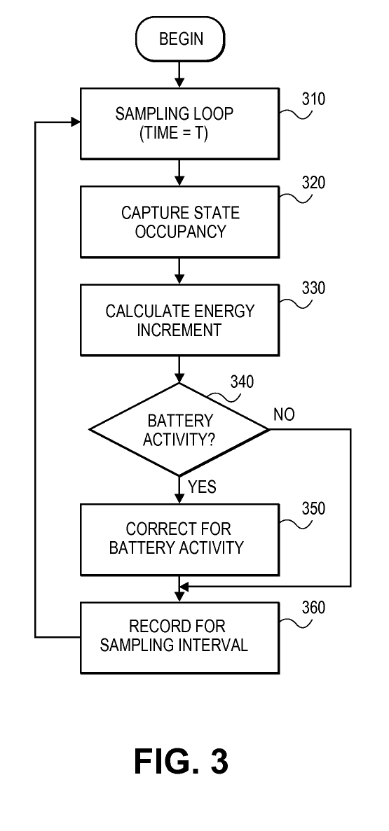

FIG. 3 is a flow diagram of one embodiment of a technique for monitoring energy usage of a platform. The example of FIG. 3 includes support for a platform with a battery (e.g., laptop computer, tablet device); however, the techniques described herein are equally applicable to platforms not having batteries (e.g., desktop computer, printer, copier, scanner).

The sampling loop is entered, 310. The sampling loop may be defined by a period of time (e.g., time=t). Any period of time may be used for the sampling period. The period of time may also be different for different platforms and/or may be different for different locations. For example, a “home” location may have one sampling loop time and other locations may have a different sampling loop time.

The operational state of the platform is captured, 320. The operational state may be captured by, for example, making system calls or by any other technique that may be used to determine the operational state of the platform. Some platforms may be configured to report operational state information, for example.

The energy increment is calculated, 330. In one embodiment, the amount of energy consumed per unit of time for an operational state is multiplied by the time for which the platform was in the operational state. Other techniques may also be utilized to estimate energy consumption. If there is no battery activity, 340, the energy consumption is recorded, 360.

If there has been battery activity, 340, corrections may be made for the battery activity, 350. Corrections for battery activity as discussed in greater detail above. The energy consumption information may be utilized locally to provide feedback to a user of the platform and/or the energy consumption information may also be transmitted to a server or other device that may aggregate energy consumption information from multiple platforms. Further, it may be provided to the platform (e.g., hardware, firmware, operating system, applications) for feedback.

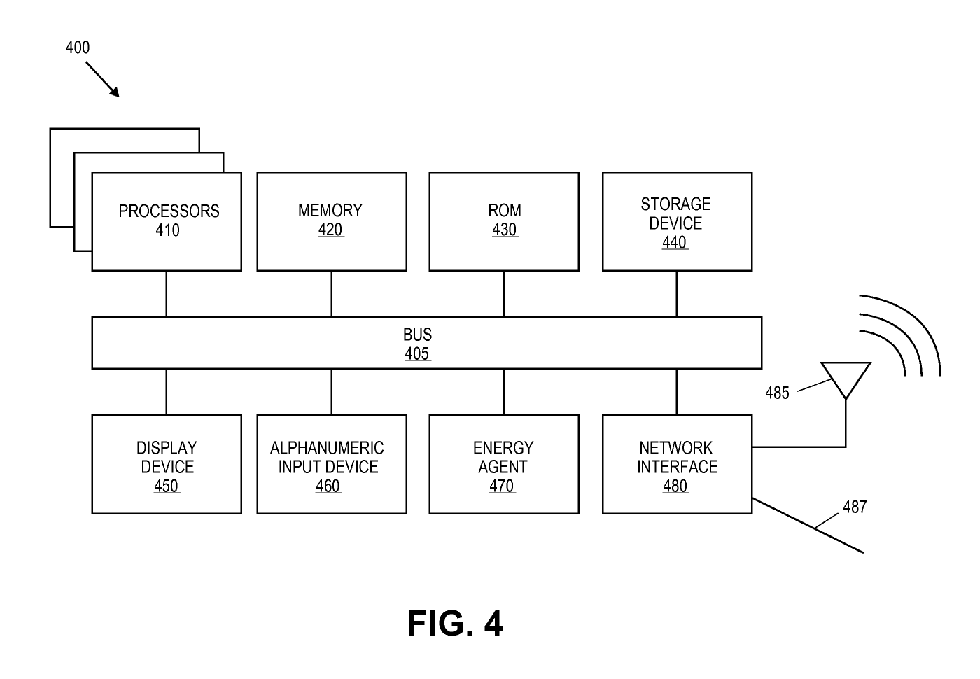

FIG. 4 is a block diagram of one embodiment of an electronic system. The electronic system illustrated in FIG. 4 is intended to represent a range of electronic systems (either wired or wireless) including, for example, desktop computer systems, laptop computer systems, cellular telephones, personal digital assistants (PDAs) including cellular-enabled PDAs, set top boxes. Alternative electronic systems may include more, fewer and/or different components.

Electronic system 400 includes bus 405 or other communication device to communicate information, and processor 410 coupled to bus 405 that may process information. While electronic system 400 is illustrated with a single processor, electronic system 400 may include multiple processors and/or co-processors. Electronic system 400 further may include random access memory (RAM) or other dynamic storage device 420 (referred to as main memory), coupled to bus 405 and may store information and instructions that may be executed by processor 410. Main memory 420 may also be used to store temporary variables or other intermediate information during execution of instructions by processor 410.

Electronic system 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled to electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device may include alphanumeric input 460 may be, for example, a mouse, a trackball, or cursor direction keys to communicate direction information and command selections to processor 410 and to control cursor movement on display 450. In one embodiment, electronic system 400 includes energy agent 470, which may be an energy agent as described herein.

Electronic system 400 further may include network interface(s) 480 to provide access to a network, such as a local area network. Network interface(s) 480 may include, for example, a wireless network interface having antenna 485, which may represent one or more antenna(e). Network interface(s) 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface(s) 480 may provide access to a local area network, for example, by conforming to IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Associated as well as previous or subsequent versions of the Bluetooth standard may also be supported.

In addition to, or instead of, communication via wireless LAN standards, network interface(s) 180 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In one embodiment, the energy consumption information is gathered without the support of a dedicated hardware power meter or sensor. That is, the platform may be self-monitoring and determine its own energy consumption information from monitoring operational states.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
monitoring one or more operational states of a platform during a period of time;
determining, for each of the one or more operational states, a portion of the period of time that the platform was in the respective one or more operational states;
receiving energy consumption information corresponding to the one or more operational states;
utilizing the energy consumption information and the portions of the period of time to determine an energy consumption for the period of time.

2. The method of claim 1 wherein monitoring one or more operational states of a platform during a period of time comprises performing one or more system calls to an operating system of the platform.

3. The method of claim 1 wherein monitoring one or more operational states of a platform during a period of time comprises accessing one or more hardware counters of the platform.

4. The method of claim 1 receiving energy consumption information corresponding to the one or more operational states comprises reading operational state energy information from a data store on the platform.

5. The method of claim 1 receiving energy consumption information corresponding to the one or more operational states comprises requesting operational state energy consumption information from a remote device via a network connection.

6. The method of claim 1 wherein utilizing the energy consumption information and the portions of the period of time to determine an energy consumption for the period of time comprises:
for each operational state, multiplying the time in the operational state by an energy consumption for the operational state;
summing the energy consumption for each operational state.

7. A computer-readable medium having stored therein instructions that, when executed, cause one or more processors to:
monitor one or more operational states of a platform during a period of time;
determine, for each of the one or more operational states, a portion of the period of time that the platform was in the respective one or more operational states;
receive energy consumption information corresponding to the one or more operational states;
utilize the energy consumption information and the portions of the period of time to determine an energy consumption for the period of time.

8. The computer-readable medium of claim 7 wherein the instructions that cause the one or more processors to monitor one or more operational states of a platform during a period of time comprise instructions that, when executed, cause the one or more processors to perform one or more system calls to an operating system of the platform.

9. The computer-readable medium of claim 7 wherein the instructions that cause the one or more processors to monitor one or more operational states of a platform during a period of time comprise instructions that, when executed, cause the one or more processors to access one or more hardware counters of the platform.

10. The computer-readable medium of claim 7 wherein the instructions that cause the one or more processors to receive energy consumption information corresponding to the one or more operational states comprise instructions that, when executed, cause the one or more processors to read operational state energy information from a data store on the platform.

11. The computer-readable medium of claim 7 wherein the instructions that cause the one or more processors to receive energy consumption information corresponding to the one or more operational states comprise instructions that, when executed, cause the one or more processors to request operational state energy consumption information from a remote device via a network connection.

12. The computer-readable medium of claim 7 wherein the instructions that cause the one or more processors to utilize the energy consumption information and the portions of the period of time to determine an energy consumption for the period of time comprise instructions that, when executed, cause the one or more processors to:
for each operational state, multiply the time in the operational state by an energy consumption for the operational state;
sum the energy consumption for each operational state.
